(19) United States
(12) Patent Application Publication
(10) Pub. No.: US 2002/0058202 A1
(43) Pub. Date: May 16, 2002

(54) Positive-working photoresist composition and photosensitive material using same

(76) Inventors: Satoshi Maemori, Sagamihara-shi (JP); Kazufumi Sato, Sagamihara-shi (JP); Kazuyuki Nitta, Ebina-shi (JP)

Correspondence Address: WENDEROTH, LIND & PONACK, L.L.P., 2033 K STREET N. W., SUITE 800, WASHINGTON, DC, 20006-1021, US

(21) Appl. No.: 09/955,111

(22) Filed: Sep. 19, 2001

(30) Foreign Application Priority Data
Sep. 19, 2000 (JP) 2000-284132

(51) Int. Cl. G03F 7/038

(52) U.S. Cl. 430/270.1; 430/311

(57) ABSTRACT

The invention discloses a chemical-amplification positive-working photoresist composition in the form of a solution which is particularly suitable for the formation, on the surface of a substrate, of a photoresist layer having a thickness of 100 to 650 nm to be in compliance with the trend toward increasing fineness of photolithographic patterning in the manufacture of semiconductor devices. The photoresist composition comprises an organic compound capable of generating an acid by exposure to actinic rays, and a film-forming resinous compound having acid-dissociable substituent groups and capable of being imparted with increased solubility in an aqueous alkaline solution by interacting with an acid and a surface active agent in an amount not exceeding 50 ppm by weight based on the resinous compound, optionally, in combination with a tertiary aliphatic amine compound and/or a carboxylic acid.

### BACKGROUND OF THE INVENTION

The present invention relates to a novel positive-working photoresist composition or, more particularly, to a chemical-amplification positive-working photoresist composition suitable for the formation of a thin photoresist layer capable of giving a patterned resist layer having a greatly decreased number of defects by the photolithographic patterning procedure in the manufacture of fine electronic devices as well as to a photosensitive photolithographic material by using the photoresist composition.

Along with the progress of the technology for the manufacture of fine electronic devices, the degree of integration in the semiconductor devices is increasing year by year as a trend in recent years and the fineness of photolithographic patterning involved therein is also rapidly increasing. For example, mass production of LSIs having patterning fineness of the design rule of 0.20 μm has already left its starting line and mass production of those having a design rule fineness of about 0.15 μm is now scheduled to rapidly approach the starting line. In order to comply with this increasing fineness of photolithographic patterning, photoresist compositions are also required to be upgraded so as to give a line-and-space pattern, hole pattern or isolated line pattern in a dimension level of 0.12 to 0.18 μm fineness by pattern-wise light-exposure with KrF excimer laser beams.

It is a known technology in the photoresist compositions of the older type containing a novolak resin and a naphthoquinonediazidosulfonic acid ester as the photosensitive ingredient to admix the composition with a surface active agent with an object to prevent occurrence of uneven coating such as striation by improving the coating workability of the photoresist solution (see Japanese Patent Kokai 7-230165). This technology of addition of a surface active agent is equally applicable to the chemical-amplification photoresist compositions.

A further trend in the technology of semiconductor device manufacturing is to employ a semiconductor silicon wafer of a larger diameter as a substrate which is under shift from the traditional 6-inch wafers to 8-inch wafers so as to improve the yield of the semiconductor devices per wafer. The photoresist compositions are also required to comply with this trend of shift in the wafer diameter. The increase in the substrate diameter is generally accompanied by an increased difficulty to ensure high uniformity of the coating layer of the photoresist composition on the substrate surface resulting in an increase of the significance of the technology of admixing the photoresist composition with a surface active agent (see Japanese Patent Kokai 2000-122289).

Another problem in recent years to accompany the increase in the fineness of photoresist layer patterning is occurrence of defects in the patterned resist layer obtained by a development treatment of the pattern-wise light-exposed photoresist layer. The defects mentioned above include adherence of scums and disorders in general in the patterned resist layer and can be detected and countered by examining the patterned resist layer after development by using a surface defects detecting instrument manufactured, for example, by KLA Tencall Co. (Model KLA).

While occurrence of defects in the patterned resist layer is not a so serious problem in the traditional photolithographic technology, a very serious problem is now caused thereby along with the great increase in the fineness of circuit wiring patterns required in the modern photolithographic patterning technology and occurrence of defects is now an important item of inspection for quality control. Namely, mass production of electrically reliable semiconductor devices in a high yield can never be accomplished unless the number of defects in a patterned resist layer is greatly decreased.

In connection with this problem, a proposal is made in Japanese Patent Kokai 2000-89463, 2000-89462, 2000-66397 and 2000-66380 that a surface active agent is admixed in a chemical-amplification positive-working photoresist composition though not to give a fully satisfactory defect-suppressing effect.

### SUMMARY OF THE INVENTION

The present invention accordingly has an object, in view of the above described situations, to provide a novel and improved chemical-amplification positive-working photoresist composition capable of remarkably decreasing occurrence of defects in patterned resist layers necessitated for realization of high-level general quality control, exhibiting excellent photosensitivity and pattern resolution as well as for being free from unevenness of the photoresist layer by virtue of improved coating workability and giving a patterned resist layer having excellently orthogonal cross sectional profile.

Thus, the chemical-amplification positive-working photoresist composition provided by the present invention comprises, as a uniform solution in an organic solvent:

(A) an organic compound capable of generating an acid by the irradiation with actinic rays; and

(B) a resinous compound capable of being imparted with increased solubility in an aqueous alkaline solution by interaction with an acid; optionally, in combination with

(C) an aliphatic tertiary amine compound; and/or

(D) a carboxylic acid compound, and contains a surface active agent in an amount not exceeding 50 ppm by weight based on the component (B).

The invention also provides a photosensitive material for photolithographic patterning which comprises, as an integral layered body:

(a) a substrate; and

(b) a layer of the chemical-amplification positive-working photoresist composition defined above formed on the surface of the substrate and having a thickness in the range from 100 to 650 nm.

### DETAILED DESCRIPTION OF THE PREFERRED EMBODIMENTS

The essential ingredients in the chemical-amplification photoresist composition of the present invention include (A) a radiation-sensitive acid-generating compound capable of releasing an acid when irradiated with actinic rays and (B) a film-forming resinous compound capable of being imparted with increased solubility in an aqueous alkaline solution in the presence of or when interacted with an acid.

The component (A) comprised in the photoresist composition used in the present invention is a compound capable of generating an acid when irradiated with actinic rays. The component (A) is not particularly limitative and can be selected from those radiation-sensitive acid-generating compounds formulated in conventional chemical-amplification photoresist compositions. Examples of suitable radiation-sensitive acid-generating compounds include diazomethane compounds, nitrobenzyl compounds, sulfonic acid esters, onium salt compounds, benzoin tosylate compounds, halogen-containing triazine compounds, cyano group-containing oximesulfonate compounds and the like, of which diazomethane compounds and onium salt compounds having a C₁-C₁₅ halogenoalkyl sulfonic acid as the anionic moiety are preferable.

Examples of the diazomethane compounds include bis(p-toluenesulfonyl)diazomethane, bis(1,1-dimethylethylsulfonyl)diazomethane, bis(cyclohexylsulfonyl)diazomethane and bis(2,4-dimethylphenylsulfonyl)diazomethane.

Examples of the above specified onium salt compounds include diphenyliodonium trifluoromethanesulfonate, bis(4-methoxyphenyl)iodonium trifluoromethanesulfonate, bis(p-tert-butylphenyl)iodonium trifluoromethanesulfonate, triphenylsulfonium trifluoromethanesulfonate, (4-methoxyphenyl)diphenylsulfonium trifluoromethanesulfonate and (p-tert-butylphenyl)diphenylsulfonium trifluoromethanesulfonate.

The resinous compound as the component (B) is exemplified by hydroxystyrene-based copolymers containing hydroxystyrene units substituted by acid-dissociable solubility-reducing groups for the hydrogen atoms of the hydroxyl groups and copolymers containing acrylic or methacrylic acid units substituted by acid-dissociable solubility-reducing groups for the hydrogen atoms of the carboxyl groups and hydroxystyrene units belonging to known class of resinous compounds formulated in chemical-amplification photoresist compositions for patterning light-exposure with KrF excimer laser beams and non-aromatic resins having polycyclic hydrocarbon groups on the main chains or in the pendant groups substituted by acid-dissociable solubility-reducing groups belonging to a known class of the resinous compounds formulated in chemical-amplification photoresist compositions for patterning light-exposure with ArF excimer laser beams. In the formulation of a photoresist composition for patterning exposure with KrF excimer laser beams suitable for baking at a relatively low temperature, in particular, a preferable resinous ingredient is a copolymer consisting of hydroxystyrene units substituted by acid-dissociable groups for the hydrogen atoms in the hydroxyl groups and unsubstituted hydroxystyrene units. The above-mentioned hydroxystyrene units can be replaced with α-methyl hydroxystyrene units.

The resinous compound as the component (B) is preferably a copolymeric resin consisting of hydroxystyrene or α-methyl hydroxystyrene units substituted for the hydroxyl hydrogen atoms by acid-dissociable solubility-reducing groups and unsubstituted hydroxystyrene or α-methyl hydroxystyrene units. The above mentioned acid-dissociable solubility-reducing substituent groups are subject to dissociation by interaction with an acid released from the component (A) to regenerate phenolic hydroxyl groups so that the resinous compound which is alkali-insoluble before light-exposure of the photoresist layer is imparted with increased solubility in an aqueous alkaline solution.

With respect to the position of the phenolic hydroxyl group on the styrenic benzene ring in the unsubstituted or substituted (α-methyl) hydroxystyrene units, the hydroxyl group can be at any of the o-, m- and p-positions relative to the carbon atom in the main chain structure of the copolymer, of which the p-position is preferable in respect of good availability of the monomeric compounds.

The above mentioned acid-dissociable solubility-reducing group is not particularly limitative and can be selected from those used for the same purpose in the resinous ingredient capable of being imparted with increased solubility in an aqueous alkaline solution by interacting with an acid as a resinous ingredient in the conventional chemical-amplification photoresist compositions for patterning exposure with KrF or ArF excimer laser beams. Examples of suitable acid-dissociable groups include tertiary alkyloxycarbonyl groups, tertiary alkyloxycarbonylalkyl groups, tertiary alkyl groups, cyclic ether groups, alkoxyalkyl groups, 1-alkyl monocycloalkyl groups and 2-alkyl polycycloalkyl groups.

Examples of tertiary alkyloxycarbonyl groups include tert-butyloxycarbonyl group and tert-amyloxycarbonyl group. Examples of tertiary alkyloxycarbonylalkyl groups include tert-butyloxycarbonylmethyl group, tert-butyloxycarbonylethyl group, tert-amyloxycarbonylmethyl group and tert-amyloxycarbonylethyl group. Examples of tertiary alkyl groups include tert-butyl group and tert-amyl group. Examples of cyclic ether groups include tetrahydropyranyl group and tetrahydrofuranyl group. Examples of alkoxyalkyl groups include 1-ethoxyethyl group and 1-methoxypropyl group. Examples of 1-alkyl monocycloalkyl groups include those 1-(lower alkyl)cyclohexyl groups of which two of the alkyl groups bonded to the tertiary carbon atom jointly form a cyclic structure such as 1-methylcyclohexyl group and 1-ethylcyclohexyl group. Examples of 2-alkylpolycycloalkyl groups include those 2-(lower alkyl)adamantyl groups of which two of the alkyl groups bonded to the tertiary carbon atom jointly form a polycyclic hydrocarbon structure such as 2-methyladamantyl group and 2-ethyladamantyl group.

A typical example of the resinous compound as the component (B) is a polyhydroxystyrene having a weight-average molecular weight in the range from 2000 to 30000 with a molecular weight dispersion of 1 to 6.0, of which from 10 to 60% of the hydroxyl hydrogen atoms are substituted by acid-dissociable solubility-reducing groups selected from tert-butyloxycarbonyl, tert-butyloxycarbonylmethyl, tert-butyl, tetrahydropyranyl, tetrahydrofuranyl, 1-ethoxyethyl and 1-methoxypropyl groups.

From the standpoint of obtaining a patterned resist layer having a high pattern resolution and excellent cross sectional profile, it is preferable that the resinous ingredient as the component (B) is a combination of two different resins including (b1) a first hydroxystyrene-based copolymer containing 10 to 60% by moles or, preferably, 10 to 50% by moles of tert-butyloxycarbonyloxy styrene groups and having a weight-average molecular weight of 2000 to 30000 or, preferably, 5000 to 25000 with a molecular weight dispersion of 1 to 6.0 or, preferably, 1 to 4.0 and (b2) a second hydroxystyrene-based copolymer containing 10 to 60% by moles or, preferably, 10 to 50% by moles of alkoxyalkyloxy styrene groups and having a weight-average molecular weight of 2000 to 30000 or, preferably, 5000 to 25000 with a molecular weight dispersion of 1 to 6.0 or, preferably, 1 to 4.0 in a weight proportion of (b1):(b2) in the range from 10:90 to 90:10 or, preferably, 10:90 to 50:50.

An alternatively preferable resinous ingredient as the component (B) is a combination of (b3) a third hydroxystyrene-based copolymer containing 10 to 60% by moles or, preferably, 10 to 50% by moles of tetrahydropyranyloxy styrene units and having a weight-average molecular weight of 2000 to 30000 or, preferably, 5000 to 25000 with a molecular weight dispersion of 1 to 6.0 or, preferably, 1 to 4.0 and the above mentioned copolymer (b2) in a weight proportion in the range from 10:90 to 90:10 or, preferably, 50:50 to 90:10.

A further preferable resinous ingredient as the component (B) is a combination of (b4) a fourth hydroxystyrene-based copolymer containing 10 to 60% by moles or, preferably, 10 to 50% by moles of tert-butoxy styrene units and having a weight-average molecular weight of 2000 to 30000 or, preferably, 5000 to 25000 with a molecular weight dispersion of 1 to 6.0 or, preferably, 1 to 4.0 and the above mentioned copolymer (b2) in a weight proportion in the range from 90:10 to 10:90 or, preferably, 50:50 to 90:10.

It is preferable in the formulation of a photoresist composition for patterning exposure with KrF excimer laser beams suitable for baking at a relatively high temperature that the resinous ingredient as the component (B) is a copolymer containing acrylic or methacrylic acid units substituted by acid-dissociable groups for the hydrogen atoms in the carboxyl groups and hydroxystyrene units. The acid-dissociable substituent groups in this case can be selected from those described above but preferably selected from tert-alkyl groups such as tert-butyl group, 1-(lower alkyl)cycloalkyl groups such as 1-methylcyclohexyl and 1-ethylcyclohexyl groups and 2-(lower alkyl)polycycloalkyl groups such as 2-methyladamantyl and 2-ethyladamantyl groups.

In order to accomplish high pattern resolution, excellent cross sectional profile and good resistance against etching, it is preferable that the resinous ingredient as the component (B) is a copolymeric resin having a weight-average molecular weight of 2000 to 30000 or, preferably, 5000 to 25000 with a molecular weight dispersion of 1 to 6.0 or, preferably, 1 to 4.0 and consisting of from 40 to 80% by moles or, preferably, from 50 to 70% by moles of hydroxystyrene units, from 10 to 40% by moles or, preferably, from 15 to 30% by moles of styrene units and from 2 to 30% by moles or, preferably, from 5 to 20% by moles of acrylic or methacrylic acid units substituted by acid-dissociable groups. The above mentioned hydroxystyrene unit and styrene unit can optionally be replaced with α-methyl hydroxystyrene unit and α-methylstyrene unit, respectively.

The above mentioned photoresist composition suitable for a baking treatment at a relatively low or high temperature is a photoresist composition of which the prebaking treatment and post-exposure baking treatment are each conducted at temperatures in the range of from 90 to 120° C. or, preferably, from 90 to 110° C. or in the range of from 110 to 150° C. or, preferably, from 120 to 140° C., respectively.

In the formulation of a photoresist composition for patterning exposure with ArF excimer laser beams, the resinous ingredient as the component (B) is preferably a non-aromatic resin having polycyclic hydrocarbon groups in the main chain structure or in the pendant groups. Examples of such a resin include those resins substituted by acid-dissociable groups and free from groups with aromaticity such as those having polycyclic groups, e.g., norbornene residues, in the main chain structure and acrylic or methacrylic acid ester resins having polycyclic hydrocarbon groups, e.g., adamantane residues, in the ester-forming portions.

Besides the monomeric units described above, it is optional that the resinous ingredient as the component (B) in the chemical-amplification positive-working photoresist composition further contains several types of other monomeric units derived from known hydroxystyrene derivatives and acrylic or methacrylic acid derivatives used in the prior art in the formulation of a chemical-amplification positive-working photoresist compositions for patterning exposure with KrF or ArF excimer laser beams each in a limited molar fraction.

In the next place, though optional, the positive-working photoresist composition used in the inventive method is compounded with (C) an aliphatic tertiary amine compound and/or (D) a carboxylic acid. The above mentioned amine compound as the component (C) has an effect of improving the holding stability of the latent images formed by pattern-wise light exposure and preventing excessive diffusion of the acid generated from the acid-generating agent by light-exposure. The above-mentioned carboxylic acid compound as the component (D) has an effect of increasing the photosensitivity of the composition and decreasing the substrate-dependency of the resist layer.

Examples of the aliphatic tertiary amine compound as the component (C) include triethylamine, tri-n-propylamine, methyl diethyl amine, dimethyl ethyl amine, triisopropylamine, tri-n-butylamine, triisobutylamine, tri-n-pentylamine, triethanolamine and tributanolamine. These amine compounds can be used either singly or as a combination of two kinds or more. The amount of the amine compound in the photoresist composition is, when used, in the range from 0.01 to 1.0 part by weight per 100 parts by weight of the resinous ingredient as the component (B).

Examples of the carboxylic acid compound as the component (D) include saturated and unsaturated aliphatic carboxylic acids, alicyclic carboxylic acids and aromatic carboxylic acids exemplified, for example, by acetic acid, propionic acid, butyric acid, lactic acid, succinic acid, benzoic acid, maleic acid, malonic acid, lauric acid, 1,1-cyclohexane dicarboxylic acid and salicylic acid. These carboxylic acid compounds can be used either singly or as a combination of two kinds or more. The amount of the component (D), when used, in the photoresist composition is in the range from 0.01 to 1.0 part by weight per 100 parts by weight of the resinous ingredient as the component (B).

In addition to the above described components (A), (B), (C) and (D), the chemical-amplification positive-working photoresist composition used in the inventive method can optionally be admixed with a variety of additives known in the art of chemical-amplification positive-working photoresist compositions such as halation inhibitors and others.

It is essential that the positive-working photoresist composition of the present invention contains a surface active agent in a concentration not exceeding 50 ppm by weight based on the amount of the component (B). This requirement can be accomplished by formulating the composition with a surface active agent in an amount as small as possible or by removing the surface active agent as completely as possible prior to application of the composition onto the substrate surface by using an adsorbent. This is because the number of defects in the resist layer after patterning cannot be decreased when the concentration of a surface active agent is too large.

The photosensitive material in the present invention can be prepared by coating the surface of a substrate conventionally employed in the photolithographic patterning works such as semiconductor silicon wafers uniformly with the above described positive-working photoresist composition. It is usual that the chemical-amplification positive-working photoresist composition comprising the above described components (A) to (D) is employed in the inventive method in the form of a uniform photoresist solution prepared by dissolving the respective ingredients in an organic solvent. Examples of suitable organic solvents include ketones such as acetone, methyl ethyl ketone, cyclohexanone, methyl isoamyl ketone and 2-heptanone, polyhydric alcohols and derivatives thereof such as ethyleneglycol, ethyleneglycol monoacetate, diethyleneglycol, diethyleneglycol monoacetate, propyleneglycol, propyleneglycol monoacetate, dipropyleneglycol and dipropyleneglycol monoacetate as well as monomethyl, monoethyl, monopropyl, monobutyl and monophenyl ethers thereof, cyclic ethers such as dioxane and esters such as methyl lactate, ethyl lactate, methyl acetate, ethyl acetate, butyl acetate, methyl pyruvate, ethyl pyruvate, methyl methoxypropionate and ethyl ethoxypropionate. These organic solvents can be used either singly or as a mixture of two kinds or more.

It is of course optional that the positive-working photoresist composition of the invention is admixed with various kinds of known additives having miscibility including auxiliary resins to improve the film properties of the resist layer, plasticizers, stabilizers and coloring agents formulated in conventional photoresist compositions.

The photoresist layer formed on a substrate surface by coating with the inventive positive-working photoresist composition should have a thickness so adjusted as to be in the range from 100 to 650 nm or, preferably, from 300 to 570 nm. Good uniformity of the coating layer formed on the surface of a substrate can be ensured and the number of defects in the finely patterned resist layer after development can be greatly decreased when the thickness is so small as above even if the concentration of a surface active agent in the composition is so low as not to exceed 50 ppm by weight.

The photoresist layer of the inventive photoresist composition can be formed directly on the substrate surface but it is optional that the substrate surface is provided with an antireflection coating film by using an antireflection coating solution in a thickness of 10 to 160 nm or, preferably, 30 to 150 nm and the photoresist layer is formed on the antireflection coating film. Intervention of an antireflection coating film between the substrate surface and the photoresist layer gives an advantage that pattern resolution of the patterned resist layer can be improved.

The procedure for the formation of a patterned resist layer by using the inventive positive-working photoresist composition comprises the steps of: forming a dried photoresist layer on the substrate surface by coating the surface with the photoresist composition in the form of a solution by using a spinner followed by drying; pattern-wise exposing the photoresist layer to a radiation such as deep ultraviolet light having a wavelength of 250 nm or shorter exemplified by KrF and ArF excimer laser beams, soft X-rays, X-rays and electron beams through a photomask bearing a desired pattern to form a latent image of the pattern followed by a post-exposure baking treatment; subjecting the photoresist layer to a development treatment with an aqueous alkaline solution as a developer such as a 0.1 to 10% by weight aqueous solution of tetramethylammonium hydroxide; and subjecting the thus patterned resist layer to a heat treatment. When the photolithographic patterning procedure is undertaken in this manner by using the inventive photoresist composition containing 50 ppm by weight or less of a surface active agent, the patterned resist layer thus formed has a remarkably decreased number of so-called defects resulting in an improvement in the yield of electrically reliable semiconductor devices.

In the following, the present invention is described in more detail by way of Examples, in which evaluation of the photoresist compositions was undertaken for the following items (1) to (5) by the respective testing procedures described there.

(1) Photosensitivity

A semiconductor silicon wafer was coated uniformly with the photoresist solution under testing by using a spinner followed by heating on a hot plate at 90° C. for 90 seconds to give a dried photoresist layer having a specified thickness. The thus formed photoresist layer was pattern-wise exposed to KrF excimer laser beams through a pattern-bearing photomask on a minifying projection exposure machine (Model FPA-3000EX3, manufactured by Canon Co.) by stepwise increasing the exposure dose with 1 mJ/cm² increments followed by a post-exposure baking treatment at 110° C. for 90 seconds. Thereafter, the photoresist layer was subjected to a development treatment with a 2.38% by weight aqueous solution of tetramethylammonium hydroxide at 23° C. for 60 seconds followed by rinse with water for 30 seconds and drying to give a patterned resist layer of which the minimum exposure dose in mJ/cm² unit resulting in complete removal of the photoresist layer on the substrate surface by the development treatment was determined and recorded as the photosensitivity of the photoresist composition.

(2) Cross Sectional Profile of Patterned Resist Layer

A line-and-space patterned resist layer of 0.25 μm line width was formed in the same manner as in (1) described above and the cross sectional profile of the line-patterned resist layer was examined on a scanning electron microscopic photograph to record the results in two ratings of: A for a profile of good orthogonality; and B for a profile with rounded shoulders and trailing skirts.

(3) Pattern Resolution

Recording was made for the critical resolution in the line-and-space patterned resist layer formed in the same manner as in (1) described above.

(4) Number of Defects

Number of the defects was counted on a silicon wafer substrate processed in the same manner as in (1) above by using a surface-defect inspection instrument (Model KLA, manufactured by KLA Co.).

(5) Unevenness of Coating

A semiconductor silicon wafer was coated with the photoresist composition prepared in (1) above and a visual inspection was immediately undertaken for occurrence of striation in the coating layer.

### EXAMPLE 1.

A positive-working photoresist composition was prepared by dissolving, in 570 parts by weight of propyleneglycol monomethyl ether acetate, a combination of 30 parts by weight of a first polyhydroxystyrene resin substituted by tert-butoxycarbonyl groups for hydrogen atoms in 39% of the hydroxyl groups and having a weight-average molecular weight of 13000 with a molecular weight dispersion of 1.2 and 70 parts by weight of a second polyhydroxystyrene resin substituted by 1-ethoxyethyl groups for hydrogen atoms in 39% of the hydroxyl groups and having a weight-average molecular weight of 13000 with a molecular weight dispersion of 1.2 as the component (B) to give a solution which was admixed with 7 parts by weight of bis(cyclohexylsulfonyl) diazomethane, 0.1 part by weight of triethylamine, 0.5 part by weight of salicylic acid and 0.001 part by weight of a fluorosilicone-based surface active agent (X-70-093, a product by Shin-Etsu Chemical Co.) followed by filtration of the solution through a membrane filter having a pore diameter of 0.2 μm.

The thus prepared photoresist composition was subjected to the evaluation test for the items (1) to (5) described above by coating a semiconductor silicon wafer therewith followed by drying to give a dried coating layer of 0.57 μm thickness. The results of the evaluation tests are shown in Table 1.

### EXAMPLE 2

The experimental procedure was substantially the same as in Example 1 described above except that, in the formulation of the photoresist composition, the resinous ingredient as the component (B) was a combination of 30 parts by weight of a third polyhydroxystyrene substituted by tetrahydropyranyl groups for the hydrogen atoms in 30% of the hydroxyl groups and having a weight-average molecular weight of 13000 with a molecular weight dispersion of 1.2 and 70 parts by weight of the same 1-ethoxyethyl group-substituted polyhydroxystyrene resin as used in Example 1. The results of the evaluation tests of the photoresist composition are shown in Table 1.

### EXAMPLE 3

The experimental procedure was substantially the same as in Example 1 described above except that, in the formulation of the photoresist composition, the resinous ingredient as the component (B) was a combination of 30 parts by weight of a fourth polyhydroxystyrene resin substituted by tert-butyl groups for the hydrogen atoms in 35% of the hydroxyl groups and having a weight-average molecular weight of 13000 with a molecular weight dispersion of 1.2 and 70 parts by weight of the same 1-ethoxyethyl group-substituted polyhydroxystyrene resin as used in Example 1 and the amount of the surface active agent was increased from 0.001 part by weight to 0.003 part by weight. The results of the evaluation tests of the photoresist composition are shown in Table 1.

### Comparative Example 1

The experimental procedure was substantially the same as in Example 1 except that, in the formulation of the photoresist composition, the surface active agent was a fluorine-containing surface active agent (R08, a product by Dai-Nippon Ink Chemical Co.) and the amount thereof was 0.05 part by weight. The results of the evaluation tests of the photoresist composition are shown in Table 1.

### Comparative Example 2

The experimental procedure was substantially the same as in Example 2 except that, in the formulation of the photoresist composition, the surface active agent was a fluorine-containing surface active agent (XR-104, a product by Dai-Nippon Ink Chemical Co.) and the amount thereof was 0.05 part by weight. The results of the evaluation tests of the photoresist composition are shown in Table 1.

### Comparative Example 3

The experimental procedure was substantially the same as in Example 3 except that the amount of the fluorosilicone-based surface active agent (X-70-093, supra) was increased from 0.001 part by weight to 0.05 part by weight. The results of the evaluation tests of the photoresist composition are shown in Table 1.

TABLE 1

| | Amount | | Cross | | | |
|---|---|---|---|---|---|---|
| | of | | sectional | | | |
| | surface | Photo- | profile of | Pattern | | |
| | active | sensi- | patterned | resolu- | Number | Uneven- |
| | agent, | tivity, | resist | tion, | of | ness of |
| | ppm | mJ/cm² | layer | μm | defects | coating |
| Exam- | 10 | 30 | A | 0.18 | 0 | No |
| ple 1 | | | | | | |
| Exam- | 10 | 32 | A | 0.17 | 0 | No |
| ple 2 | | | | | | |
| Exam- | 30 | 30 | A | 0.18 | 0 | No |
| ple 3 | | | | | | |
| Compa- | 500 | 30 | B | 0.18 | 900 | No |
| rative | | | | | | |
| Exam- | | | | | | |
| ple 1 | | | | | | |
| Compa- | 500 | 32 | B | 0.17 | 1300 | No |
| rative | | | | | | |
| Exam- | | | | | | |
| ple 2 | | | | | | |
| Compa- | 500 | 30 | B | 0.18 | 1000 | No |
| rative | | | | | | |
| Exam- | | | | | | |
| ple 3 | | | | | | |

What is claimed is:

1. A chemical-amplification positive-working photoresist composition suitable for the formation of a photoresist layer having a thickness in the range from 100 to 650 nm on the surface of a substrate which comprises, as a uniform solution in an organic solvent:
an organic acid-generating compound capable of generating an acid by the irradiation with actinic rays;
a resinous compound having acid-dissociable groups and capable of being imparted with increased solubility in an aqueous alkaline solution by interaction with an acid; and
a surface active agent in a concentration not exceeding 50 ppm by weight based on the amount of the resinous compound.

2. The chemical-amplification positive-working photoresist composition as claimed in claim 1 in which the resinous compound is a hydroxystyrene-based copolymer comprising Imonomeric units of hydroxystyrene substituted by acid-dissociable groups for the hydrogen atoms in the hydroxyl groups.

3. The chemical-amplification positive-working photoresist composition as claimed in claim 1 in which the resinous compound is a hydroxystyrene-based copolymer comprising monomeric units of hydroxystyrene, monomeric units of styrene and monomeric units of acrylic or methacrylic acid substituted by acid-dissociable groups for the hydrogen atoms in the carboxyl groups.

4. The chemical-amplification positive-working photoresist composition as claimed in claim 1 in which the acid-dissociable group is selected from the group consisting of tertiary alkyloxycarbonyl groups, tertiary alkyloxycarbonylalkyl groups, tertiary alkyl groups, cyclic ether groups, alkoxyalkyl groups, 1-alkyl monocycloalkyl groups and 2-alkyl polycycloalkyl groups.

5. The chemical-amplification positive-working photoresist composition as claimed in claim 4 in which the acid-dissociable group is selected from the group consisting of tert-butyloxycarbonyl group, tert-butyloxycarbonylmethyl group, tert-butyl group, tetrahydropyranyl group, tetrahydrofuranyl group, 1-ethoxyethyl group, 1-methoxypropyl group, 1-methylcyclohexyl group, 1-ethylcyclohexyl group, 2-methyladamantyl group and 2-ethyladamantyl group.

6. The chemical-amplification positive-working photoresist composition as claimed in claim 2 in which the resinous compound comprises the monomeric units of hydroxystyrene substituted for the hydrogen atoms in the hydroxyl groups by acid-dissociable groups selected from the group consisting of tert-butyloxycarbonyl group, tert-butyloxycarbonylmethyl group, tert-butyl group, tetrahydropyranyl group, tetrahydrofuranyl group, 1-ethoxyethyl group and 1-methoxypropyl group in a molar fraction of 10 to 60%.

7. The chemical-amplification positive-working photoresist composition as claimed in claim 2 in which the resinous compound is a combination of (b1) a first polyhydroxystyrene-based copolymer having a weight-average molecular weight of 2000 to 30000 with a molecular weight dispersion of 1 to 6.0 and comprising from 10 to 60% by moles of monomeric units of tert-butyloxycarbonyloxystyrene and (b2) a second polyhydroxystyrene-based copolymer having a weight-average molecular weight of 2000 to 30000 with a molecular weight dispersion of 1 to 6.0 and comprising from 10 to 60% by moles of monomeric units of alkoxyalkyloxystyrene in a (b1):(b2) weight proportion in the range from 10:90 to 90:10.

8. The chemical-amplification positive-working photoresist composition as claimed in claim 2 in which the resinous compound is a combination of (b3) a third polyhydroxystyrene-based copolymer having a weight-average molecular weight of 2000 to 30000 with a molecular weight dispersion of 1 to 6.0 and comprising from 10 to 60% by moles of monomeric units of tetrahydropyranyloxystyrene and (b2) a second polyhydroxystyrene-based copolymer having a weight-average molecular weight of 2000 to 30000 with a molecular weight dispersion of 1 to 6.0 and comprising from 10 to 60% by moles of monomeric units of alkoxyalkyloxystyrene in a (b3):(b2) weight proportion in the range from 10:90 to 90:10.

9. The chemical-amplification positive-working photoresist composition as claimed in claim 2 in which the resinous compound is a combination of (b4) a fourth polyhydroxystyrene-based copolymer having a weight-average molecular weight of 2000 to 30000 with a molecular weight dispersion of 1 to 6.0 and comprising from 10 to 60% by moles of monomeric units of tert-butoxystyrene and (b2) a second polyhydroxystyrene-based copolymer having a weight-average molecular weight of 2000 to 30000 with a molecular weight dispersion of 1 to 6.0 and comprising from 10 to 60% by moles of monomeric units of alkoxyalkyloxystyrene in a (b4):(b2) weight proportion in the range from 10:90 to 90:10.

10. The chemical-amplification positive-working photoresist composition as claimed in claim 1 in which the organic acid-generating compound is capable of generating an acid by the irradiation with KrF excimer laser beams.

11. The chemical-amplification positive-working photoresist composition as claimed in claim 1 in which the resinous compound is a resin without aromaticity having a polycyclic hydrocarbon group in the main chain structure or in the pendant group.

12. The chemical-amplification positive-working photoresist composition as claimed in claim 1 in which the organic acid-generating compound is capable of generating an acid by the irradiation with ArF excimer laser beams.

13. The chemical-amplification positive-working photoresist composition as claimed in claim 1 which further comprises from 0.01 to 1 part by weight of a tertiary aliphatic amine compound per 100 parts by weight of the resinous compound.

14. The chemical-amplification positive-working photoresist composition as claimed in claim 1 which further comprises from 0.01 to 1 part by weight of a carboxylic acid compound per 100 parts by weight of the resinous compound.

15. A photosensitive material for photolithographic patterning which comprises, as an integral layered body:
(a) a substrate; and
(b) a photoresist layer having a thickness in the range from 100 to 650 nm formed on the surface of the substrate from the chemical-amplification positive-working photoresist composition defined in claim 1.

16. The photosensitive material as claimed in claim 15 in which an antireflection coating film having a thickness in the range from 10 to 160 nm intervenes between the substrate surface and the photosensitive layer.

17. The photosensitive material as claimed in claim 15 in which the photoresist layer has a thickness in the range from 300 to 570 nm.
